(19) United States
(12) Patent Application Publication
(10) Pub. No.: US 2013/0095658 A1
(43) Pub. Date: Apr. 18, 2013

(54) METAL ORGANIC CHEMICAL VAPOR DEPOSITION METHOD AND APPARATUS

(71) Applicants: Chih-Yung Huang, Taichung City (TW); Szu-Hao Chen, Changhua County (TW); Ching-Chiun Wang, Miaoli County (TW); Chien-Chih Chen, Taichung City (TW)

(72) Inventors: Chih-Yung Huang, Taichung City (TW); Szu-Hao Chen, Changhua County (TW); Ching-Chiun Wang, Miaoli County (TW); Chien-Chih Chen, Taichung City (TW)

(73) Assignee: INDUSTRIAL TECHNOLOGY RESEARCH INSTITUTE, Hsinchu (TW)

(21) Appl. No.: 13/470,346

(22) Filed: May 13, 2012

(30) Foreign Application Priority Data
Oct. 13, 2011 (TW) 100137191

(51) Int. Cl. H01L 21/285; C23C 16/46

(52) U.S. Cl. 438/681; 118/725; 257/E21.161

(57) ABSTRACT

A metal organic chemical vapor deposition (MOCVD) method and apparatus are provided. The MOCVD method includes: providing a substrate, in which a metal-based material layer is disposed on a first surface of the substrate; putting the substrate on a base in a chamber, in which the metal-based material layer is between the substrate and the base; and performing a MOCVD process on a second surface opposite to the first surface. The difference in thermal conductivity between the metal-based material layer and the substrate is in the range of 1 W/m° C. to 20 W/m° C., and the thermal expansion coefficients of the metal-based material layer and the substrate are of the same order.

### CROSS-REFERENCE TO RELATED APPLICATION

This application claims the priority benefit of Taiwan application serial no. 100137191, filed on Oct. 13, 2011. The entirety of the above-mentioned patent application is hereby incorporated by reference herein and made a part of this specification.

### TECHNICAL FIELD

The disclosure relates to a metal organic chemical vapor deposition (MOCVD) method and apparatus.

### BACKGROUND

In the MOCVD process, a high temperature is required; however, the high temperature in the process may cause deterioration of the properties of elements. For instance, the light emitting diode (LED) binning depends on the wavelength uniformity, and is directly influenced by the distribution of the component indium (In). However, indium is sensitive to the temperature, and the overall wavelength uniformity changes with the slight variation of the temperature. Therefore, thermal field uniformity is one of the key technologies for improving the LED binning.

At present, in order to improve the LED binning, efforts are made to improve the temperature uniformity, for example, adjusting the temperature by using an internal and an external temperature control system, or by using a rotary base. However, the temperature uniformity presented by adopting the manners is limited.

In addition, when the temperature difference between the substrate and the MOCVD apparatus is excessively high, substrate warping always occurs, and substrate breaking is caused in especially serious cases, resulting in defective products. Therefore, an on-line detection system for measuring substrate warping is provided during the whole manufacturing process at present.

US Patent No. U.S. Pat. No. 7,314,519B2 discloses a method of replacing a part of the material of a base with the same material of a substrate, so that the thermal resistance of a heat transfer path involving the substrate is identical to that of a heat transfer path not involving the substrate.

### SUMMARY

A MOCVD method is introduced herein, which is used to prevent the occurrence of substrate warping during a process.

A MOCVD apparatus is further introduced herein, which can be used to perform MOCVD at a high temperature, and improve the fabricated element binning.

The disclosure provides a MOCVD method, which includes: providing a substrate, in which a metal-based material layer is disposed on a first surface of the substrate; putting the substrate on a base in a chamber, in which the metal-based material layer is between the substrate and the base; and performing a MOCVD process on a second surface of the substrate opposite to the first surface. The difference in thermal conductivity between the metal-based material layer and the substrate is in the range of 1 W/m° C. to 20 W/m° C., and the thermal expansion coefficients of the metal-based material layer and the substrate are of the same order.

The disclosure further provides a MOCVD apparatus, which at least includes a chamber and a base. The base is located in the chamber, and is used for supporting and heating a substrate. In the apparatus, a metal-based material layer is located between the substrate and the base, in which the difference in thermal conductivity between the metal-based material layer and the substrate is in the range of 1 W/m° C. to 20 W/m° C., and the thermal expansion coefficients of the metal-based material layer and the substrate are of the same order.

Based on the above, according to the MOCVD method and apparatus of the disclosure, by controlling the differences in thermal conductivity and thermal expansion coefficient between the metal-based material layer located between the base and the substrate, and the substrate in a certain range, the process temperature uniformity is improved, thereby preventing the occurrence of warping or even breaking of the substrate during the high-temperature process of MOCVD. In addition, the metal-based material layer can also serve as an electrode of a semiconductor device, thus effectively reducing the cost.

Several exemplary embodiments accompanied with figures are described in detail below to further describe the disclosure in details.

### BRIEF DESCRIPTION OF THE DRAWINGS

The accompanying drawings are included to provide further understanding, and are incorporated in and constitute a part of this specification. The drawings illustrate exemplary embodiments and, together with the description, serve to explain the principles of the disclosure.

FIG. 1 is a schematic three-dimensional diagram illustrating an example of an LED fabricated following MOCVD steps according to an exemplary embodiment.

FIG. 2 is a front diagram illustrating a MOCVD apparatus according to another exemplary embodiment.

FIG. 3 is a three-dimensional diagram illustrating a part of members of the MOCVD apparatus in FIG. 2 in a variation example.

### DETAILED DESCRIPTION OF DISCLOSED EMBODIMENTS

An exemplary embodiment provides a MOCVD method. According to the exemplary embodiment of the disclosure, before MOCVD, a substrate is first provided, in which a metal-based material layer is disposed on a first surface of the substrate. The difference in thermal conductivity between the metal-based material layer and the substrate is in the range of 1 W/m° C. to 20 W/m° C.; and the thermal expansion coefficients of the metal-based material layer and the substrate are of the same order, that is, the difference is less than 10 folds. For example, the metal-based material layer can resist a temperature of 1000° C. or higher, and preferably 1500° C. or higher. The electrical resistivity of the metal-based material layer is, for example, of the same order, such as in the range of 1×10⁻⁹ to 10×10⁻⁹ Ω·m. In addition, the thickness of the metal-based material layer is, for example, in the range of 1 μm to 10 μm, and optionally, the metal-based material layer may be entirely formed on the first surface of the substrate. When a metal that can resist a high temperature and has a high thermal conductivity such as molybdenum is used, besides preventing the influence of erosion by gas is prevented during the epitaxy process, the metal molybdenum can serve as a good conductive layer, so the electrode of the finally formed semiconductor device can be directly replaced by the metal-based material layer made of molybdenum.

In this exemplary embodiment, if the substrate is a sapphire substrate, the material of the metal-based material layer may be selected from tantalum (Ta), niobium (Nb), and the like. When the substrate is a silicon substrate, the material of the metal-based material layer may be molybdenum (Mo). The metal-based material layer includes a metal or a metal compound, for example, molybdenum (Mo), tantalum (Ta), niobium (Nb), or platinum (Pt).

Then, the substrate is put on a base in a chamber, and the metal-based material layer is between the substrate and the base. The base is, for example, a base made of graphite. Then, a MOCVD process is performed on a second surface of the substrate opposite to the first surface. In addition, the base is rotated during the MOCVD process, which facilitates the temperature uniformity, in which the base is rotated at a rotation rate lower than 20 rpm; and preferably 10 rpm. In addition, during the MOCVD process, gas is evenly introduced into the chamber according to actual process requirements.

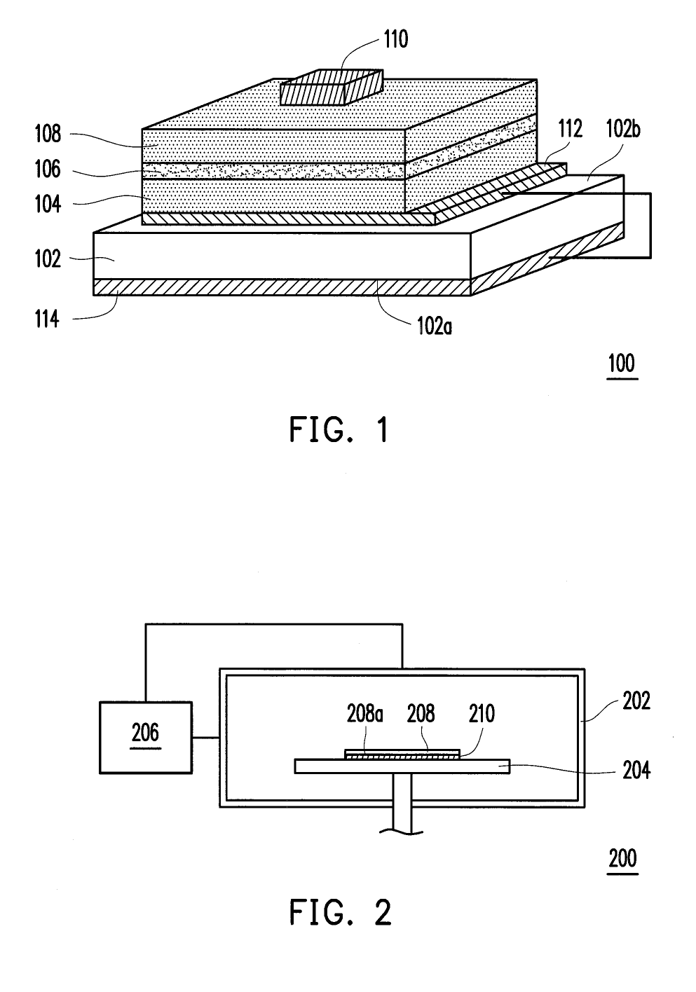

When the metal-based material layer according to this exemplary embodiment is a material layer formed on the first surface of the substrate, the metal-based material layer can further be used as an electrode of a semiconductor device fabricated in the MOCVD process, as shown in FIG. 1.

FIG. 1 is a schematic three-dimensional diagram illustrating an example of an LED fabricated following MOCVD steps according to an exemplary embodiment. In FIG. 1, an LED 100 substantially includes a substrate 102, a P-type semiconductor layer 104 formed at a second surface 102b side of the substrate 102, multi-quantum well (MQW) structures 106, and an N-type semiconductor layer 108. In addition, an N-type electrode 110 is disposed on the N-type semiconductor layer 108, and a bonding metal layer 112 is between the P-type semiconductor layer 104 and the second surface 102b of the substrate 100. The metal-based material layer 114 mentioned in the foregoing exemplary embodiment is formed on a first surface 102a of the substrate 102, and a stay may be used as a P-type electrode of the LED 100. Therefore, by using the metal-based material layer 114 as one of the electrodes, an LED epitaxy process may be omitted, which is beneficial to reduce the cost.

Although an LED process is used as an example in this exemplary embodiment, the disclosure is not limited thereto. Any semiconductor process in which high-temperature treatment is required can adopt the method of this exemplary embodiment, so as to prevent the occurrence of substrate warping, and improve binning.

FIG. 2 is a front diagram illustrating a MOCVD apparatus according to another exemplary embodiment.

Referring to FIG. 2, in this exemplary embodiment, a MOCVD apparatus 200 at least includes a chamber 202 and a base 204 located in the chamber 202. In addition, the MOCVD apparatus 200 may further has a gas supply system 206, connected to the chamber 202. In the apparatus 200, the base 204 is used for supporting and heating a substrate 208, and a metal-based material layer 210 is between the substrate 208 and the base 204. The difference in thermal conductivity between the metal-based material layer 210 and the substrate 208 is in the range of 1 W/m° C. to 20 W/m° C., and the thermal expansion coefficients of the metal-based material layer 210 and the substrate 208 are of the same order. As for other parameters of the metal-based material layer 210, reference can be made to those of the metal-based material layer in the foregoing exemplary embodiment.

In this exemplary embodiment, the metal-based material layer 210 is, for example, entirely formed on a surface 208a of the substrate 208, such that the substrate 208 and the base 204 do not contact each other.

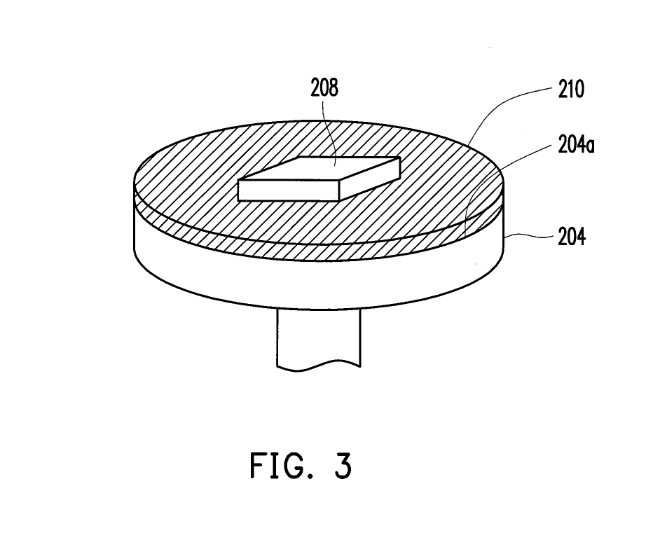

In addition, optionally, the metal-based material layer 210 in the exemplary embodiment may also be disposed on a surface 204a of the base 204, as shown in FIG. 3. FIG. 3 is a three-dimensional diagram illustrating relation of the base 204, the metal-based material layer 210, and the substrate 208 disposed on the metal-based material layer 210. Other members of the MOCVD apparatus are similar to those in FIG. 2.

The results of this exemplary embodiment are verified below by several simulation tests.

Simulation Test 1

In a MOCVD apparatus, the diameter of the whole chamber was 24 cm, a 6-inch sapphire substrate was placed, and the simulation conditions were: the pressure was 100 torr, the flow rate was 30 SLM, and the rotation rate of a graphite base was 10 rpm, a chamber wall was a cold wall maintained at about 25° C., the base was maintained at 1050° C., an air gap between the base and a metal-based material (molybdenum) layer was set to be 10 μm, several metal-based material layers with different thickness (1 mm, 10 μm) were disposed, the gas was air with a density of 1.1614 kg/m³ and a viscosity coefficient of 1.846E-5 kg/m-s.

The thermal conductivities of molybdenum, graphite and sapphire were respectively 138 W/mK, 100 W/mK, and 15 W/mK, the flow rate at a gas inlet was assumed to be even, and an annular exhaust vent with a height of 2 mm was used. The simulation results are shown in Table 1.

It can be known from Table 1 that, when the thickness of the metal-based material layer is respectively 1 mm and 10 μm, the temperature difference is respectively 1.127° C. and 0.362° C., and it can be known from the thermal resistance formula that, the thickness has influence on the thermal resistance, and the thermal resistance increases with the increase of the thickness, so the effect obtained when the thickness is 10 μm is superior to that obtained when the thickness is 1 mm.

TABLE 1

| | Tmax (° C.) | Tmin (° C.) | ΔT (° C.) |
|---|---|---|---|
| Having no metal-based | 1321.584 | 1307.61 | 13.974 |
| material layer | | | |
| 1 mm | 1262.231 | 1261.104 | 1.127 |
| 1 μm | 1275.315 | 1274.494 | 0.821 |
| 5 μm | 1288.578 | 1288.054 | 0.524 |
| 10 μm | 1306.386 | 1306.024 | 0.362 |

Simulation Test 2

In a MOCVD apparatus, the diameter of the whole chamber was 24 cm, a 2-inch and 8-inch sapphire substrates were respectively used as a substrate, and the simulation condition were: the pressure was 100 torr, the flow rate was 30SLM, and the rotation rate of a graphite base was 10 rpm, a chamber wall was a cold wall maintained at about 25° C., a base was maintained at 1050° C., an air gap between the base and a metal-based material (molybdenum) layer was set to be 10 μm, the gas was air with a density of 1.1614 kg/m³ and a viscosity coefficient of 1.846E-5 kg/m-s.

Then, simulation was carried out with several metal-based material layers with different thicknesses (0.1 μm-1 mm), the flow rate at a gas inlet was assumed to be even, and an annular exhaust vent with a height of 2 mm was used. The simulation results are shown in Table 2.

It can be known from Table 2 that, the deformation (δₘₐₓ) of the substrate decreases with the decrease of the thickness of the film. In Table 2, the plus amd minus denote the warping direction.

TABLE 2

| 1050° C. | 2-inch substrate | | | 8-inch substrate | | |
|---|---|---|---|---|---|---|
| Film thickness | κ (1/m) | δₘₐₓ (μm) | θ (°) | κ (1/m) | δₘₐₓ (μm) | θ (°) |
| 1 μm | +0.06966 | 21.7686 | 0.1996 | +0.03322 | 166.089 | 0.3806 |
| 5 μm | −0.07964 | −24.8861 | −0.2281 | −0.03845 | −192.227 | −0.4406 |
| 10 μm | −0.2571 | −80.3437 | −0.7365 | −0.12250 | −624.818 | −1.4320 |
| 1 mm | −1.4939 | −466.849 | −4.2798 | −1.4189 | −7094.42 | −16.2592 |

To sum up, in the disclosure, by disposing the metal-based material layer between the base and the substrate and selecting the differences in thermal conductivity and thermal expansion coefficient between the metal-based material layer and the substrate in a specific range, the process temperature uniformity is improved, thereby preventing the occurrence of warping or even breaking of the substrate during the process. In addition, the metal-based material layer can also serve as an electrode of a semiconductor device, thus effectively reducing the cost.

It will be apparent to those skilled in the art that various modifications and variations can be made to the structure of the disclosed embodiments without departing from the scope or spirit of the disclosure. In view of the foregoing, it is intended that the disclosure cover modifications and variations of this disclosure provided they fall within the scope of the following claims and their equivalents.

What is claimed is:

1. A metal organic chemical vapor deposition (MOCVD) method, comprising:
providing a substrate, wherein a metal-based material layer is disposed on a first surface of the substrate;
putting the substrate on a base in a chamber, wherein the metal-based material layer is between the substrate and the base; and
performing a MOCVD process on a second surface of the substrate opposite to the first surface, wherein
the difference in thermal conductivity between the metal-based material layer and the substrate is in the range of 1 W/m° C. to 20 W/m° C.; and
the thermal expansion coefficients of the metal-based material layer and the substrate are of the same order.

2. The MOCVD method according to claim 1, wherein the metal-based material layer is capable of resisting a temperature of 1000° C. or higher.

3. The MOCVD method according to claim 1, wherein the electrical resistivity of the metal-based material layer is of the same order.

4. The MOCVD method according to claim 1, wherein the thickness of the metal-based material layer is in the range of 1 μm to 10 μm.

5. The MOCVD method according to claim 1, wherein the MOCVD process is performed, such that a semiconductor device is formed on the second surface of the substrate.

6. The MOCVD method according to claim 5, wherein the metal-based material layer is an electrode of the semiconductor device.

7. The MOCVD method according to claim 1, wherein the metal-based material layer comprises a metal or a metal compound.

8. The MOCVD method according to claim 7, wherein the metal-based material layer comprises molybdenum (Mo), tantalum (Ta), niobium (Nb) or platinum (Pt).

9. The MOCVD method according to claim 1, wherein the metal-based material layer is entirely formed on the first surface of the substrate.

10. The MOCVD method according to claim 1, further comprising rotating the base during perfroming the MOCVD process.

11. The MOCVD method according to claim 10, wherein a rotation rate is lower than 20 rpm when rotating the base.

12. The MOCVD method according to claim 1, further comprising evenly introducing gas in the chamber during perfroming the MOCVD process.

13. A MOCVD apparatus, at least comprising:
a chamber; and
a base, located in the chamber, and for supporting and heating a substrate, wherein
a metal-based material layer is located between the substrate and the base;
the difference in thermal conductivity between the metal-based material layer and the substrate is in the range of 1 W/m° C. to 20 W/m° C.; and
the thermal expansion coefficients of the metal-based material layer and the substrate are of the same order.

14. The MOCVD apparatus according to claim 13, wherein the metal-based material layer is capable of resisting a temperature of 1000° C. or higher.

15. The MOCVD apparatus according to claim 13, wherein the electrical resistivity of the metal-based material layer is of the same order.

16. The MOCVD apparatus according to claim 13, wherein the thickness of the metal-based material layer is in the range of 1 μm to 10 μm.

17. The MOCVD apparatus according to claim 13, wherein the metal-based material layer comprises a metal or a metal compound.

18. The MOCVD apparatus according to claim 17, wherein the metal-based material layer comprises molybdenum (Mo), tantalum (Ta), niobium (Nb) or platinum (Pt).

19. The MOCVD apparatus according to claim 13, wherein the metal-based material layer is entirely formed on a surface of the substrate.

20. The MOCVD apparatus according to claim 13, wherein the metal-based material layer is located on a surface of the base.

21. The MOCVD apparatus according to claim 13, wherein the substrate and the base do not contact each other.

22. The MOCVD apparatus according to claim 13, further comprising a gas supply system, connected to the chamber.
